(19) United States
(12) Patent Application Publication
(10) Pub. No.: US 2006/0281289 A1
(43) Pub. Date: Dec. 14, 2006

(54) Method of forming polycide layer and method of manufacturing semiconductor device having polycide layer

(75) Inventors: Young-Cheon Kim, Suwon-si (KR); Chul Hwangbo, Suwon-si (KR); Rak-Hwan Kim, Suwon-si (KR); Hyeon-Deok Lee, Seoul (KR); In-Sun Park, Yongin-si (KR); Ji-Soon Park, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/446,981

(22) Filed: Jun. 6, 2006

(30) Foreign Application Priority Data
Jun. 9, 2005 (KR) 2005-49294

(51) Int. Cl. H01L 21/4763

(52) U.S. Cl. 438/592

(57) ABSTRACT

In a method of forming a polycide layer and method of manufacturing a semiconductor device having the polycide layer, the method may include forming a preliminary polysilicon layer doped with first type impurities on a substrate having a first region and a second region, implanting second type of impurities into a portion of the preliminary polysilicon layer on the second region, heat treating the preliminary polysilicon layer to electrically activate the impurities, removing a portion of an upper surface of the heat treated preliminary polysilicon layer to obtain a polysilicon layer, forming a metal silicide layer on the polysilicon layer, and patterning the polysilicon layer and the metal silicide layer to form a first type gate electrode on the first region and to form a second type gate electrode on the second region.

### CLAIM OF PRIORITY

A claim of priority is made under 35 USC § 119 to Korean Patent Application No. 2005-49294 filed on Jun. 9, 2005 the disclosure of which is hereby incorporated herein by reference in its entirety as if set forth fully herein.

### BACKGROUND

1. Field

Example embodiments of the present invention relate to a method of forming a polycide layer and a method of manufacturing a semiconductor device having a polycide layer. More particularly, example embodiments of the present invention relate to a method of forming a polycide layer including a doped polysilicon layer and a tungsten silicide layer and a method of manufacturing a semiconductor device having a polycide layer.

2. Description of the Related Art

A multilayered structure, for example, a polycide structure, which may include a doped polysilicon pattern and a tungsten silicide pattern, has been used as a gate electrode of a semiconductor memory device, for example, a Dynamic Random Access Memory (DRAM). The tungsten silicide pattern may decrease electrical resistance of a gate electrode, and the doped polysilicon pattern may prevent deterioration of a gate dielectric layer.

A tungsten silicide layer may be formed by a chemical vapor deposition (CVD) using reaction gases including WF₆, SiH₄, H₂, etc. However, a tungsten silicide layer formed using SiH₄ gas may have a high concentration of fluorine. Fluorine in a tungsten silicide layer may diffuse into a gate dielectric layer thereby deteriorating electrical characteristics of the gate dielectric layer. Further, fluorine in the tungsten silicide layer may promote diffusion of impurities, for example, boron and phosphorus, from the doped polysilicon layer into the tungsten silicide layer thereby deteriorating operating performances of the semiconductor device.

Moreover, the tungsten silicide layer formed using SiH₄ gas may have poor step coverage and/or a poor adhesion property. If a post annealing process is performed to improve the step coverage and/or adhesion properties, defects, for example, cracking and/or delamination of the tungsten silicide layer, may occur.

To overcome some of the problems described above, a CVD process using WF₆ and SiH₂Cl₂ (dichlorosilane; DCS) gases may be used.

When a gate electrode having a polycide structure is employed in a complementary metal oxide semiconductor (CMOS) transistor, a surface profile of a tungsten silicide layer may be deteriorated by a rapid thermal annealing (RTA) process, which may be used to form a gate electrode.

For example, impurities in a doped polysilicon layer may be extracted onto a surface of the doped polysilicon layer, and impurity concentration may increase at a surface portion of the doped polysilicon layer during the RTA process. Thus, a surface profile of the doped polysilicon layer may be deteriorated.

Surface conditions of the tungsten silicide layer may be determined by the surface profile of the underlying polysilicon layer. In other words, since a tungsten silicide layer may have good thickness uniformity and/or step coverage, the surface profile of the tungsten silicide layer may be deteriorated by the extracted impurities on the doped polysilicon layer or agglomeration, which may be caused by material migration at a surface portion of the doped polysilicon layer.

Further, a patterning process on the tungsten silicide layer and the doped polysilicon layer to form the gate electrode may be difficult because of the deterioration of the surface profiles.

### SUMMARY

Example embodiments of the present invention may provide a method of forming a polycide layer having a more uniform surface profile.

Example embodiments of the present invention also may provide a method of manufacturing a semiconductor device using the method of forming the polycide layer.

In an example embodiment of the present invention, a method of forming a polycide layer may include forming a preliminary polysilicon layer doped with first type impurities on a substrate, partially implanting second type impurities into the preliminary polysilicon layer, heat treating the preliminary polysilicon layer to electrically activate the impurities, removing a portion of an upper surface of the heat treated preliminary polysilicon layer to obtain a polysilicon layer, and forming a metal silicide layer on the polysilicon layer.

In another example embodiment of the present invention, a method of manufacturing a semiconductor device may include forming a preliminary polysilicon layer doped with first type impurities on a substrate having a first region and a second region, implanting second type of impurities into a portion of the preliminary polysilicon layer on the second region, heat treating the preliminary polysilicon layer to electrically activate the impurities, removing a portion of an upper surface of the heat treated preliminary polysilicon layer to obtain a polysilicon layer, forming a metal silicide layer on the polysilicon layer, and patterning the polysilicon layer and the metal silicide layer to form a first type gate electrode on the first region and to form a second type gate electrode on the second region.

### BRIEF DESCRIPTION OF THE DRAWINGS

Example embodiments of the present invention will become readily apparent from the following detailed description when considered in conjunction with the accompanying drawings wherein:

FIGS. 1-8 are cross-sectional views illustrating a method of manufacturing a semiconductor device in accordance with an example embodiment of the present invention;

FIG. 9 is a schematic view illustrating surface defects of a polycide layer caused by a conventional method; and

FIG. 10 is a schematic view illustrating surface defects of a polycide layer caused by a method according to an example embodiment of the present invention.

### DESCRIPTION OF EXAMPLE EMBODIMENTS

Example embodiments of the present invention now will be described more fully hereinafter with reference to the accompanying drawings, in which example embodiments of the invention are shown. This invention may, however, be embodied in many different forms and should not be construed as limited to the example embodiments set forth herein. Rather, these example embodiments are provided so that this disclosure will be thorough and complete, and will fully convey the scope of the invention to those skilled in the art. Like reference numerals refer to like elements throughout.

It will be understood that when an element is referred to as being “on” another element, it can be directlv on the other element or intervening elements may be present. In contrast, when an element is referred to as being “directly on” another element, there are no intervening elements present. As used herein, the term “and/or” includes any and all combinations of one or more of the associated listed items.

It will be understood that, although the terms first, second, etc. may be used herein to describe various elements, these elements should not be limited by these terms. These terms are only used to distinguish one element from another. For example, a first thin film could be termed a second thin film, and, similarly, a second thin film could be termed a first thin film without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Example embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

Hereinafter. example embodiments of the present invention will be explained in detail with reference to the accompanying drawings.

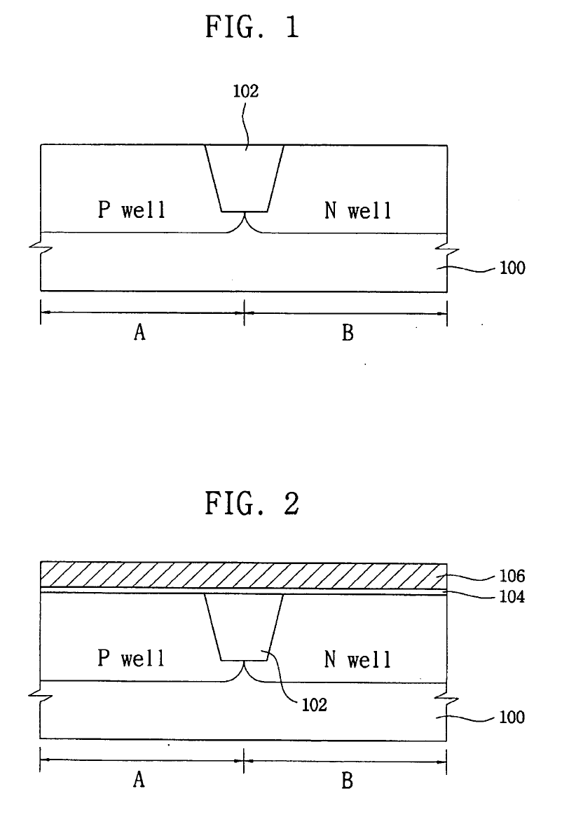

FIGS. 1 to 8 are cross-sectional views illustrating a method of manufacturing a semiconductor device in accordance with an example embodiment of the present invention;

Referring to FIG. 1, a surface portion of a semiconductor substrate 100, for example, a silicon wafer may be divided into an active region and a field region by a device isolation process. A plurality of active regions may be defined by an isolation layer using a local oxidation of silicon (LOCOS) process or a shallow trench isolation (STI) process.

For example, the semiconductor substrate 100 may be divided into a first region A for the formation of an NMOS device and a second region B for the formation of a PMOS device. Alternatively, the semiconductor substrate 100 may be divided into a DRAM formation region and a logic formation region.

After a sacrificial oxide layer (not shown) is formed on the substrate 100 by a thermal oxidation process or a CVD process, a P-well doped with p-type impurities may be formed at the first region A, and an N-well doped with n-type impurities may be formed at the second region B.

The P-well and N-well may be formed by photolithography and ion implantation processes. A first photoresist pattern (not shown) for exposing the first region A may be formed on the semiconductor substrate 100, and the P-well may be formed by implanting p-type impurities into the first region A using the first photoresist pattern as an ion implantation mask. A second photoresist pattern (not shown) for exposing the second region B may be formed on the semiconductor substrate 100, and the N-well may be formed by implanting n-type impurities into the second region B using the second photoresist pattern as an ion implantation mask.

The first and second photoresist patterns may be removed by ashing and stripping processes. After forming the P-well and N-well, a heat treatment may be performed at a temperature of about 900 to about 1000° C. to cure damage, which may have resulted from the ion implantation process, and to electrically activate the p-type and n-type impurities.

The sacrificial oxide layer may be removed by a wet etching process using a wet etchant, for example, a mixture of NH₄OH, H₂O₂ and H₂O, generally referred to as standard cleaning (SCl) solution; a mixture of HF and H₂O (a diluted HF solution); a mixture of NH₄F, HF and H₂O, generally referred to as a limulus amoebocyte lysate (LAL) solution, and the like.

Referring to FIG. 2, a gate oxide layer 104 used as a gate dielectric layer may be formed on the first and second regions A and B. The gate oxide layer 104 may be formed by a rapid thermal oxidation process, a furnace thermal oxidation process, a plasma oxidation process, and the like. For example, in accordance with the rapid thermal oxidation process, the gate oxide layer 104 may be formed by heating the semiconductor substrate 100 to a temperature of about 800 to 950° C. and supplying a reaction gas including oxygen onto the semiconductor substrate 100. Alternatively, a portion of the gate oxide layer 104 may be converted into a silicon oxynitride (SiON) layer by nitriding the gate oxide layer 104. The SiON layer may be formed to reduce or prevent impurities in a subsequently formed gate electrode from diffusing into a channel region beneath the gate oxide layer 104.

The gate oxide layer 104 may have different thicknesses at the first and second regions A and B. For example, in the case that the first region A is a DRAM formation region and the second region B is a logic formation region, a portion of the gate oxide layer 104 on the first region A may have a thickness greater than that of a portion of the gate oxide layer 104 on the second region B, because operating voltage applied to a semiconductor device on the DRAM formation region may be relatively high as compared with a semiconductor device on the logic formation region.

A preliminary polysilicon layer 106 doped with impurities may be formed to a thickness of about 500 to about 2000 Å on the gate oxide layer 104. The preliminary polysilicon layer 106 may be formed by a low temperature chemical vapor deposition (LPCVD) process using SiH₄ gas. The preliminary polysilicon layer 106 may be in-situ doped with n-type impurities during the LPCVD process. For example, the preliminary polysilicon layer 106 may be in-situ doped using PH₃ gas. Alternatively, the preliminary polysilicon layer 106 may be doped by an ion implantation or diffusion process.

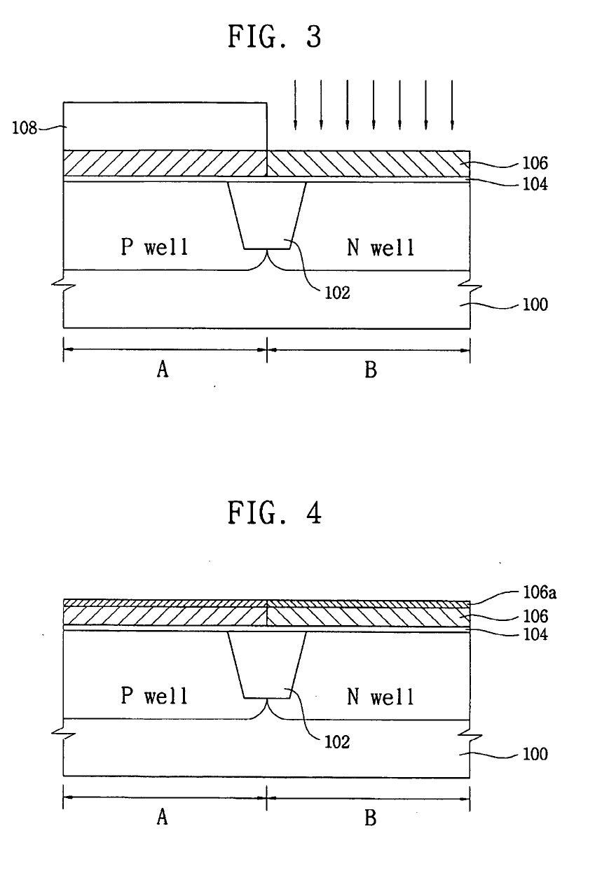

Referring to FIG. 3, a third photoresist pattern 108 may be formed on the preliminary polysilicon layer 106 to expose a portion of the preliminary polysilicon layer 106 on the second region B, and the exposed portion of the preliminary polysilicon layer 106 on the second region B may be doped with p-type impurities. For example, the exposed portion of the preliminary polysilicon layer 106 may be doped with p-type impurities including boron (B) using an ion implantation process.

As described above, though implanted to form the PMOS device on the second region B, the p-type impurities may be implanted to adjust a work function of the gate electrode. For example, in an NMOS transistor, p-type impurities may be implanted into a gate electrode doped with n-type impurities to adjust a work function of the gate electrode.

Referring to FIG. 4, after removing the third photoresist pattern 108, a heat treatment may be performed to electrically activate the p-type impurities and to cure damage caused by the ion implantation process. For example, a rapid thermal annealing process may be performed at a temperature of about 900 to 1000° C. for period from about a few seconds to dozens of seconds.

Impurities in the preliminary polysilicon layer 106 may migrate toward an upper surface of the preliminary polysilicon layer 106 during the heat treatment, and thus a surface profile of the preliminary layer 106 may deteriorate due to material migration. Silicon agglomeration due to the material migration may form a plurality of protrusions having a diameter of about 0.1 to about 0.2 μm on the upper surface of the preliminary polysilicon layer 106. The protrusions may deteriorate a surface profile of a metal silicide layer, which may be formed during a subsequent metal silicide layer formation process.

In the case that a tungsten suicide layer is employed as the metal silicide layer, the tungsten silicide layer may have a poor surface profile because of good step coverage thereof and the deteriorated surface profile of the preliminary layer 106. Further, during the formation of the tungsten silicide layer, PF₃ may be generated by a reaction between WF₆ supplied to form the tungsten silicide layer and phosphorus (P) in the preliminary polysilicon layer 106, thereby deteriorating electrical characteristics of the tungsten silicide layer. Therefore, an upper surface portion 106a of the preliminary polysilicon layer 106 having a relatively high impurity concentration after the heat treatment should be removed.

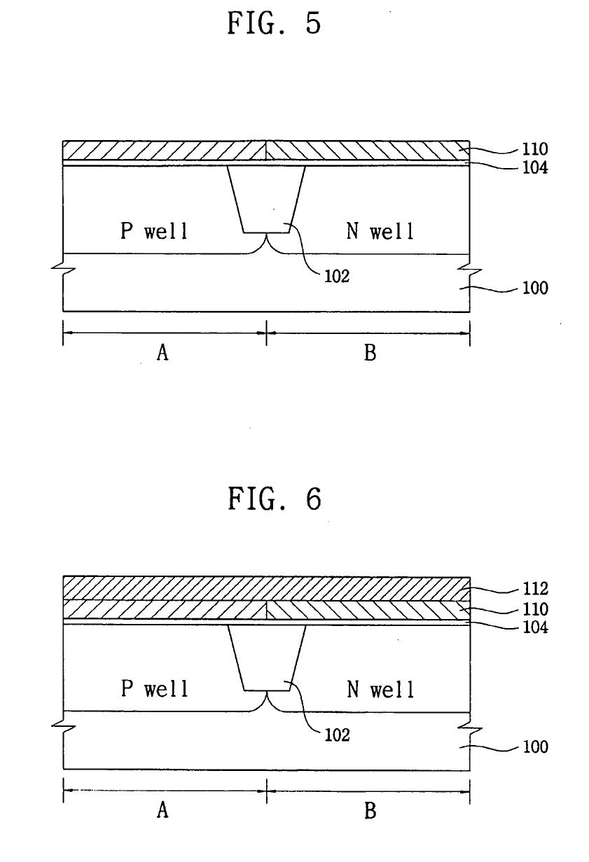

Referring to FIG. 5, a polysilicon layer 110 having a desired thickness may be obtained by removing the upper surface portion 106a of the preliminary polysilicon layer 106. A removed thickness of the upper surface portion 106a may be about 20 to about 200 Å, and a thickness of the preliminary polysilicon layer 106 may be determined in consideration of the to-be-removed thickness of the upper surface portion 106a.

The upper surface portion 106a may be removed by various methods known to those skilled in the art. For example, the upper surface portion 106a may be removed by a RF sputtering process using argon (Ar) gas. In the case of performing an RF sputtering process, Ar plasma may be formed in a process chamber in which the semiconductor substrate 100 may be positioned, and bias power may be applied to a stage supporting the semiconductor substrate 100. Argon ions in the argon plasma collide with the upper surface portion 106a due to the applied bias power thereto, which selectively removes the upper surface portion 106a.

Alternatively, the upper surface portion 106a of the preliminary polysilicon layer 106 may be removed by a chemical mechanical polishing (CMP) process, a dry etching process using etching gas including fluorine, a wet etching process using etching solution including sulfuric acid, and the like.

Referring to FIG. 6, a polycide layer may be constructed by forming a metal silicide layer 112 on the polysilicon layer 110. For example, a tungsten silicide layer may be formed to a thickness of about 500 to about 1000 Å by a CVD process using WF₆ and DCS gases.

The tungsten silicide layer 112 may have a uniform surface profile because the tungsten silicide layer 112 may be formed on the polysilicon layer 110 having an improved surface profile.

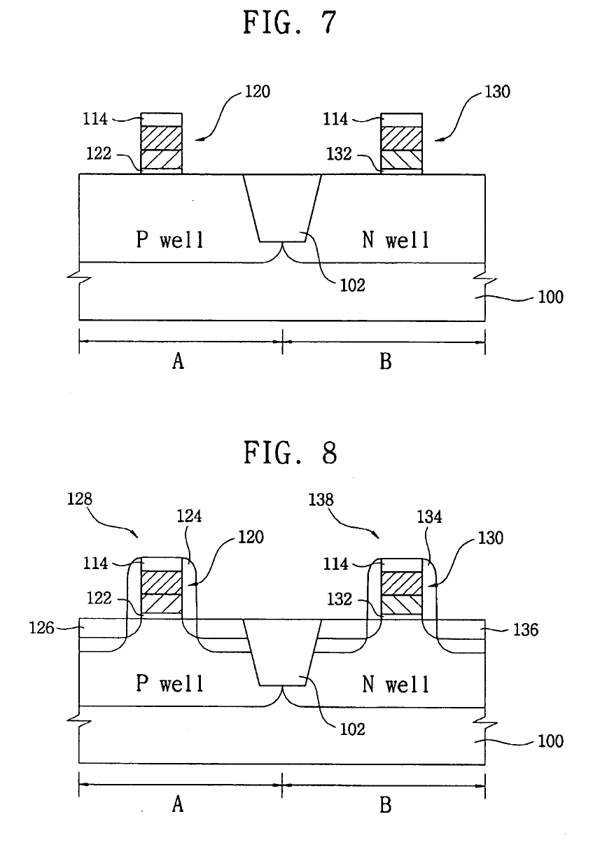

Referring to FIG. 7, mask patterns 114 may be formed on the tungsten silicide layer 112. By performing an anisotropic etching process using the mask patterns 114 as an etching mask, an n-type gate electrode 120 and a first gate oxide layer pattern 122 may be formed on the first region A, and a p-type gate electrode 130 and a second gate oxide layer pattern 132 may be formed on the second region B.

A mask layer (not shown) may be formed on the tungsten silicide layer 112. The mask layer may include silicon nitride, and may be formed by a LPCVD or a plasma enhanced chemical vapor deposition (PECVD) process using a silicon source gas, for example, DCS, SiH₄, and the like, and a nitriding gas, for example, NH₃ gas.

A fourth photoresist pattern (not shown) may be formed on the mask layer. The mask layer may be etched using the fourth photoresist pattern as an etching mask to form the mask patterns 114 on the tungsten silicide layer 112. The n-type and p-type gate electrodes 120 and 130 and the first and second gate oxide layer patterns 122 and 132 may be formed by an anisotropic etching process using the mask patterns 114 as an etching mask.

Referring to FIG. 8, spacers 124 and 134 may be formed on side surfaces of the n-type and p-type gate electrodes 120 and 130, and impurity regions 126 and 136, which may be used as source/drain regions, may be formed at surface portions of the semiconductor substrate 100 adjacent to the n-type and p-type gate electrodes 120 and 130, thereby constructing an NMOS transistor 128 and a PMOS transistor 138 on the first region A and the second region B, respectively.

The spacers 124 and 134 may be formed by forming a silicon nitride layer on surfaces of the mask pattern 114, the n-type and p-type gate electrodes 120 and 130 and the semiconductor substrate 100 using a LPCVD process, and anisotropically etching the silicon nitride layer until surfaces of the mask patterns 114 and the semiconductor substrate 100 are exposed.

The impurity regions 126 and 136 may be formed by repeatedly performing a photolithography process and an ion implantation process.

A fifth photoresist pattern (not shown) may be formed to expose the n-type gate electrode 120 and the first spacers 124, and n-type impurities may be implanted into surface portions of the semiconductor substrate 100 in the first region A using the fifth photoresist pattern as an ion implantation mask to thereby form the NMOS transistor 128 on the first region A.

A sixth photoresist pattern (not shown) may be formed to expose the p-type gate electrode 130 and the second spacers 134, and p-type impurities may be implanted into surface portions of the semiconductor substrate 100 in the second region B using the sixth photoresist pattern as an ion implantation mask to thereby form the PMOS transistor 138 on the first region B.

The impurity regions 126 and 136 may include a low concentration impurity region and a high concentration impurity region, respectively. The low concentration impurity regions may be formed prior to the formation of the spacers 124 and 134, and the high concentration impurity regions may be formed after the formation of the spacers 124 and 134.

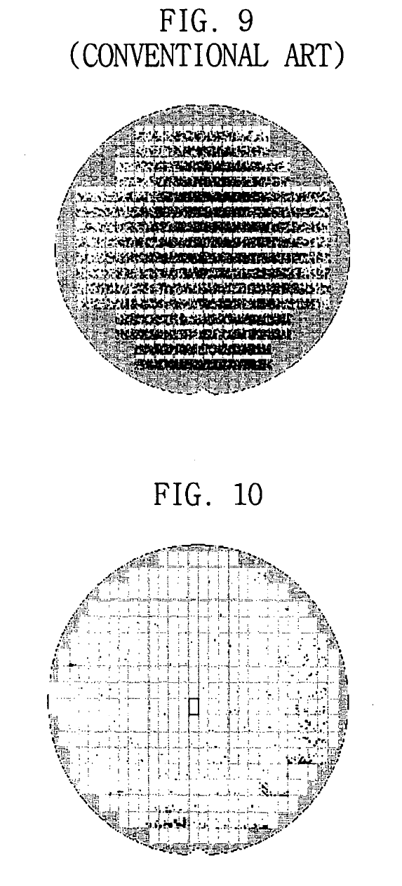

FIG. 9 is a schematic view illustrating surface defects of a polycide layer caused by a conventional method, and FIG. 10 is a schematic view illustrating surface defects of a polycide layer caused by a method of an example embodiment of the present invention.

In FIG. 9, a polysilicon layer was formed on a semiconductor substrate using a conventional method. After a heat treatment on a polysilicon layer, a tungsten silicide layer was formed on the heat treated polysilicon layer.

In FIG. 10, in accordance with an example embodiment of the present invention, a tungsten silicide layer 112 was formed on a polysilicon layer 110 after removing an upper surface portion 106a from a preliminary polysilicon layer 106. A desired thickness of the tungsten silicide layer 112, which was to be formed by an RF sputtering method, was 50 Å.

As shown in FIGS. 9 and 10, defects generated on the tungsten silicide layer manufactured by the conventional method were higher in number as compared with the tungsten silicide layer 112 manufactured according to an example embodiment of the present invention. Specifically, as shown in FIGS. 9 and 10, the number of defects in FIG. 9 was about 17,527, and the number of defects in FIG. 10 was about 1,198.

Though not shown in the figures, a semiconductor device having a CMOS structure may be constructed by forming electric wiring extending from the impurity regions 126 and 136.

As described above, although used to manufacture a semiconductor device having a CMOS structure, a method of forming a polycide layer according to example embodiments of the present invention may be employed in various technical fields of the art. For example, a method of forming a polycide layer according to example embodiments of the present invention may be employed to form a control gate electrode of a flash memory device, and also manufacture a merged DRAM and Logic (MDL) device including a DRAM region and a logic region or a merged Flash and Logic (MFL) device including a flash memory region and a logic region.

Further, in the case that an oxide layer for an etching mask is formed at a high temperature on a peripheral region of a semiconductor substrate after a doped polysilicon layer formed on a cell region of a semiconductor substrate, defects due to material migration and/or silicon agglomeration may be generated on a surface of the doped polysilicon layer. Accordingly, a method of formed a polycide layer in accordance to example embodiments of the present invention may be used when a heat treatment or a high temperature process is accompanied after forming a doped polysilicon layer.

According to example embodiments of the present invention, defects generated on a doped polysilicon layer by subsequently accompanied heat treatment or high temperature process may be reduced by performing an RF sputtering process. Accordingly, surface uniformity or surface profile of a tungsten silicide layer may be improved in a subsequent tungsten silicide formation process.

Although example embodiments of the present invention have been described, it is understood that the present invention should not be limited to these example embodiments but various changes and modifications may be made by one skilled in the art within the scope of the example embodiments of the present invention.

What is claimed is:

1. A method of forming a polycide layer comprising:
forming a preliminary polysilicon layer doped with first type impurities on a substrate;
partially implanting second type impurities into the preliminary polysilicon layer;
heat treating the preliminary polysilicon layer to electrically activate the second type impurities;
removing a portion of an upper surface of the heat treated preliminary polysilicon layer to obtain a polysilicon layer; and
forming a metal silicide layer on the polysilicon layer.

2. The method of claim 1, wherein the portion of the upper surface is removed by a RF sputtering process using argon gas.

3. The method of claim 1, wherein a thickness removed from the portion of the upper surface is about 20 to about 200 Å.

4. The method of claim 1, wherein the preliminary polysilicon layer is formed by a low pressure chemical vapor deposition process using SiH₄ gas and an in-situ doping process using PH₃ gas.

5. The method of claim 1, wherein the second type impurities are p-type impurities, the first impurities are n-type impurities, and the p-type impurities are implanted by an ion implantation process.

6. The method of claim 1, wherein partially implanting the second type impurities includes:
forming a photoresist pattern on the preliminary polysilicon layer to expose a portion of the preliminary polysilicon layer; and
implanting the second type impurities into the exposed portion of the preliminary polysilicon layer.

7. The method of claim 1, wherein the metal silicide layer includes tungsten silicide.

8. The method of claim 7, wherein the tungsten silicide layer is formed by a chemical vapor deposition process using WF₆ and SiH₂Cl₂ gases.

9. A method of manufacturing a semiconductor device comprising:
forming the polysilicon layer of claim 1; and
patterning the polysilicon layer and the metal silicide layer to form a first type gate electrode in a first region and to form a second type gate electrode in a second region.

10. The method of claim 9, wherein the portion of the upper surface is removed by an RF sputtering process using argon gas.

11. The method of claim 9, wherein a thickness removed from the upper surface portion is about 20 to about 200 Å.

12. The method of claim 9, wherein the preliminary polysilicon layer is formed by a low pressure chemical vapor deposition process using SiH₄ gas and an in-situ doping process using PH₃ gas.

13. The method of claim 9, wherein the second type of impurities are p-type impurities, the first type impurities are n-type impurities, and the p-type impurities are implanted by an ion implantation process.

14. The method of claim 9, wherein partially implanting the second type of impurities includes:
forming a photoresist pattern on the preliminary polysilicon layer to expose a portion of the preliminary polysilicon layer in the second region; and
implanting the second type impurities into the exposed portion of the preliminary polysilicon layer using the photoresist pattern as an ion implantation mask.

15. The method of claim 9, wherein the metal silicide layer includes tungsten silicide.

16. The method of claim 15, wherein the tungsten silicide layer is formed by a chemical vapor deposition process using WF₆ and SiH₂Cl₂ gases.

17. The method of claim 9, further comprising:
forming a gate dielectric layer on the substrate prior to forming the preliminary polysilicon layer.

18. The method of claim 17, wherein a thickness of the gate dielectric layer on the first region is different than on the second region.

19. The method of claim 9, further comprising:
forming first type impurity regions at surface portions of the substrate adjacent to the first type gate electrode and forming second type impurity regions at surface portions of the substrate adjacent to the second type gate electrode.
